(19) United States
(12) Patent Application Publication
(10) Pub. No.: US 2024/0263309 A1
(43) Pub. Date: Aug. 8, 2024

(54) ATOMIC LAYER DEPOSITION APPARATUS

(71) Applicant: Samsung Display Co., Ltd., Yongin-si (KR)

(72) Inventors: WOO-SEOK JEON, Yongin-si (KR); CHULMIN BAE, Yongin-si (KR); Jaehee SEO, Yongin-si (KR)

(73) Assignee: Samsung Display Co., Ltd., Yongin-si (KR)

(21) Appl. No.: 18/479,233

(22) Filed: Oct. 2, 2023

(30) Foreign Application Priority Data
Feb. 6, 2023 (KR) 10-2023-0015666

(51) Int. Cl. C23C 16/455; C23C 16/52

(52) U.S. Cl. CPC C23C 16/45544; C23C 16/45529; C23C 16/52

(57) ABSTRACT

An atomic layer deposition apparatus includes a source gas supply part that supplies multiple source gases, a source gas supply module connected to the source gas supply part, a reaction gas supply part that supplies a reaction gas, a reaction gas supply module connected to the reaction gas supply part and spaced apart from the source gas supply module in a first direction, and a first purge gas supply module disposed between the source gas supply module and the reaction gas supply module.

### CROSS REFERENCE TO RELATED APPLICATION(S)

This application claims priority to and benefits of Korean Patent Application No. 10-2023-0015666 under 35 U.S.C. § 119, filed on Feb. 6, 2023, in the Korean Intellectual Property Office (KIPO), the entire contents of which are incorporated herein by reference.

### BACKGROUND

### 1. Technical Field

The disclosure relates to an atomic layer deposition apparatus.

### 2. Description of the Related Art

In general, physical vapor deposition (PVD), chemical vapor deposition (CVD), or the like is used as a way of depositing a thin layer on a substrate. However, because an increasing reduction in size of semiconductor devices requires fine-patterned thin layers, there has been a great increase in atomic layer deposition (ALD) with depositing more fine thin layers.

The atomic layer deposition is a process in which an atomic layer is stacked layer-by-layer to form a fine thin layer. The atomic layer deposition is divided into an adsorption step, a substitution step, and a creation step.

In the adsorption step, a process chamber is provided with a precursor in a gaseous state, and the precursor is adsorbed on a surface of a substrate. In the substitution step, the process chamber is provided with a reactant in a gaseous state, and a chemical substitution reaction may be performed between the reactant and the precursor adsorbed on the substrate. In the creation step, the chemical substitution reaction may create a layer with a material different from the precursor and the reactant. The created layer, as one atomic layer, may be adsorbed on the surface of the substrate. In such a process, one layer may be deposited and formed on the substrate.

As the process forms one atomic layer on the substrate, as the process is repeated, another atomic layer may be continuously stacked on the substrate. Such process may be repeatedly performed to form a thin layer to a required thickness. Because a thin layer is deposited layer-by-layer on the substrate, the thin layer may be formed to have a required thickness.

In case that one thin layer is formed, an atomic layer deposition apparatus includes a single module for injecting a precursor gas and a reactant gas. In contrast, in case that multiple different thin layers are formed, the atomic layer deposition apparatus includes multiple modules. In forming the different thin layers, the atomic layer deposition apparatus may have an increased size.

### SUMMARY

The disclosure provides an atomic layer deposition apparatus including a single source gas supply module.

According to an embodiment of the disclosure, an atomic layer deposition apparatus may include a source gas supply part that supplies a plurality of source gases, a source gas supply module connected to the source gas supply part, a reaction gas supply part that supplies a reaction gas, a reaction gas supply module connected to the reaction gas supply part and spaced apart from the source gas supply module in a first direction, and a first purge gas supply module disposed between the source gas supply module and the reaction gas supply module.

In an embodiment, the source gas supply part may include a first source gas supply part that supplies a first source gas, a second source gas supply part that supplies a second source gas, and a third source gas supply part that supplies a third source gas.

In an embodiment, the source gas supply module may include a plurality of first source gas nozzles connected to the first source gas supply part, a plurality of second source gas nozzles connected to the second source gas supply part, and a plurality of third source gas nozzles connected to the third source gas supply part.

In an embodiment, one of the plurality of first source gas nozzles, one of the plurality of second source gas nozzles, and one of the plurality of third source gas nozzles may be repeatedly arranged in sequence.

In an embodiment, the atomic layer deposition apparatus may further include a first valve that connects the first source gas supply part to the plurality of first source gas nozzles and controls a supply of the first source gas, a second valve that connects the second source gas supply part to the plurality of second source gas nozzles and controls a supply of the second source gas, and a third valve that connects the third source gas supply part to the plurality of third source gas nozzles and controls a supply of the third source gas. The first, second, and third valves may be sequentially opened.

In an embodiment, each of the first, second, and third valves may include a first valve part, a second valve part, a third valve part, and a fourth valve part. An end of the first valve part and an end of the second valve part may be connected to a corresponding one of the first, second, and third source gas supply parts. Another end of the second valve part may be connected to an end of the third valve part. Another end of the first valve part may be connected to another end of the third valve part. The fourth valve part may be supplied with a carrier gas and be connected to the end of the third valve part. The another end of the third valve part may be connected to a corresponding one of the plurality of first source gas nozzles, the plurality of second source gas nozzles, and the plurality of third source gas nozzles.

In an embodiment, the source gas supply module may receive and supply the first, second, and third source gases to a substrate. The reaction gas supply module may receive and supply the reaction gas to the substrate. The first purge gas supply module may supply a purge gas to the substrate. In case that the first, second, and third source gases are supplied, the first, second, and fourth valve parts may be opened and the third valve part may be closed. In case that the supplies of the first, second, and third source gases are interrupted, the first and second valve parts may be closed, and the third and fourth valve parts may be opened.

In an embodiment, the atomic layer deposition apparatus may further include a carrier gas supply part that supplies the carrier gas.

In an embodiment, the atomic layer deposition apparatus may further include a second purge gas supply module, and a third purge gas supply module. The source gas supply module may be disposed between the first purge gas supply module and the second purge gas supply module. The reaction gas supply module may be disposed between the first purge gas supply module and the third purge gas supply module.

In an embodiment, exhaust holes may be defined between the source gas supply module and the first purge gas supply module and between the reaction gas supply module and the first purge gas supply module.

In an embodiment, the atomic layer deposition apparatus may further include a pumping module connected to the exhaust holes and providing an exhaust pressure to the exhaust holes.

In an embodiment, the atomic layer deposition apparatus may further include a first valve that connects the first source gas supply part to the plurality of first source gas nozzles, the plurality of second source gas nozzles, and the plurality of third source gas nozzles and controls a supply of the first source gas, a second valve that connects the second source gas supply part to the plurality of first source gas nozzles, the plurality of second source gas nozzles, and the plurality of third source gas nozzles and controls a supply of the second source gas, and a third valve that connects the third source gas supply part to the plurality of first source gas nozzles, the plurality of second source gas nozzles, and the plurality of third source gas nozzles and controls a supply of the third source gas. The first, second, and third valves may be sequentially opened.

In an embodiment, the atomic layer deposition apparatus may further include a first flow controller connected to the first valve and controlling a flow rate of the first source gas, a second flow controller connected to the second valve and controlling a flow rate of the second source gas, a third flow controller connected to the third valve and controlling a flow rate of the third source gas, and a mixture part connected to the first, second, and third flow controllers and to the plurality of first source gas nozzles, the plurality of second source gas nozzles, and the plurality of third source gas nozzles, mixing the first, second, and third source gases that are provided from the first, second, and third flow controllers, and supplying the mixed first, second, and third source gases to the plurality of first source gas nozzles, the plurality of second source gas nozzles, and the plurality of third source gas nozzles.

In an embodiment, the flow rates of the first, second, and third source gases may be independently controlled by the first, second, and third flow controllers.

In an embodiment, the source gas supply module may include a plurality of first source gas nozzles, a plurality of second source gas nozzles, and a plurality of third source gas nozzle, which supply different ones of the plurality of source gases. Each of the plurality of first source gas nozzles may include a first source hole, each of the plurality of second source gas nozzles may include a second source hole, each of the plurality of third source gas nozzles may include a third source hole, the first source hole, the second source hole, and the third source hole of neighboring ones of the plurality of first source gas nozzles, the plurality of second source gas nozzles, and the plurality of third source gas nozzles may be arranged in a diagonal direction. The diagonal direction may be a direction that intersects the first direction and a second direction intersecting the first direction. The source gas supply module may extend in the second direction.

In an embodiment, the plurality of source gases may be mixed in the source gas supply part and supplied to the source gas supply module.

In an embodiment, the plurality of source gases may be mixed at different ratios.

According to an embodiment of the disclosure, an atomic layer deposition apparatus may include a first source gas supply part that supplies a first source gas, a second source gas supply part that supplies a second source gas, a third source gas supply part that supplies a third source gas, a source gas supply module connected to the first, second, and third source gas supply parts, a first valve that connects the first source gas supply part to the source gas supply module and controls a supply of the first source gas, a second valve that connects the second source gas supply part to the source gas supply module and controls a supply of the second source gas, a third valve that connects the third source gas supply part to the source gas supply module and controls a supply of the third source gas, a reaction gas supply part that supplies a reaction gas, a reaction gas supply module connected to the reaction gas supply part and spaced apart from the source gas supply module in a first direction, and a first purge gas supply module disposed between the source gas supply module and the reaction gas supply module.

In an embodiment, the first, second, and third valves may be sequentially opened.

In an embodiment, the source gas supply module may include a plurality of first source gas nozzles connected through the first valve to the first source gas supply part, a plurality of second source gas nozzles connected through the second valve to the second source gas supply part, and a plurality of third source gas nozzles connected through the third valve to the third source gas supply part.

### BRIEF DESCRIPTION OF DRAWINGS

FIG. 1 is a schematic perspective view illustrating an atomic layer deposition apparatus according to an embodiment of the disclosure.

FIGS. 2A to 2C are schematic simplified cross-sectional views illustrating an atomic layer deposition method.

FIG. 3 is a schematic cross-sectional view illustrating a pixel including a thin layer formed using an atomic layer deposition apparatus of FIG. 1.

FIG. 4 is a schematic cross-sectional view taken along line I-I′ of FIG. 1.

FIG. 5 is a schematic cross-sectional view taken along line II-II′ of FIG. 1.

FIG. 6 is a schematic diagram illustrating a second valve connected to a second source gas supply part of FIG. 5.

FIG. 7 is a schematic cross-sectional view taken along line III-III′ of FIG. 1.

FIG. 8A is a schematic cross-sectional view illustrating a process in which a substrate is supplied with a first source gas.

FIG. 8B is a schematic diagram illustrating a process in which a substate is supplied with a first source gas.

FIG. 9 is a schematic diagram illustrating a process in which a substrate is supplied with a first source gas, a reaction gas, and a purge gas.

FIG. 10 is a schematic diagram illustrating an operation of a first valve after a first source gas is deposited on a substrate.

FIG. 11A is a schematic cross-sectional view illustrating a process in which a substrate is supplied with a second source gas.

FIG. 11B is a schematic diagram illustrating a process in which a substrate is supplied with a second source gas.

FIG. 12 is a schematic diagram illustrating a process in which a substrate is supplied with a second source gas, a reaction gas, and a purge gas.

FIG. 13 is a schematic diagram illustrating an operation of a second valve after a second source gas is deposited on a substrate.

FIG. 14A is a schematic cross-sectional view illustrating a process in which a substrate is supplied with a third source gas.

FIG. 14B is a schematic diagram illustrating a process in which a substrate is supplied with a third source gas.

FIG. 15 is a schematic diagram illustrating a process in which a substrate is supplied with a third source gas, a reaction gas, and a purge gas.

FIG. 16 is a schematic diagram illustrating an operation of a third valve after a third source gas is deposited on a substrate.

FIG. 17 is a schematic diagram illustrating a source gas supply module according to an embodiment of the disclosure.

FIG. 18 is a schematic diagram illustrating an atomic layer deposition apparatus according to an embodiment of the disclosure.

FIG. 19 is a schematic diagram illustrating an atomic layer deposition apparatus according to an embodiment of the disclosure.

FIG. 20 is a schematic diagram illustrating an atomic layer deposition apparatus according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The terminology used herein is for the purpose of describing particular embodiments and is not intended to be limiting. As used herein, the singular forms, “a,” “an,” and “the” are intended to include the plural forms as well, unless the context clearly indicates otherwise. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

In this description, when a certain component (or area, layer, portion, location, region, substrate, etc.) is referred to as being “on” or “connected to” other component(s), the certain component may be directly disposed on or directly connected to the other component(s) or at least one intervening component may be present therebetween. When, however, an element or layer is referred to as being “directly on” or “directly connected to” another element or layer, there are no intervening elements or layers present. To this end, the term “connected” may refer to physical, electrical, and/or fluid connection, with or without intervening elements. Further, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another.

When a component is described herein to “connect” another component to the other component or to be “connected to” other components, the components may be connected to each other as separate elements, or the components may be integral with each other.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some example embodiments may be physically separated into two or more interacting and discrete blocks, units, and/or modules without departing from the scope of the disclosure. Further, the blocks, units, and/or modules of some example embodiments may be physically combined into more complex blocks, units, and/or modules without departing from the scope of the disclosure.

Like numerals indicate like components. Moreover, in the drawings, thicknesses, ratios, and dimensions of components are exaggerated for effectively explaining the technical contents.

The term “and/or” includes one or more combinations defined by associated components. For example, “A and/or B” may be understood to mean “A, B, or A and B.” The terms “and” and “or” may be used in the conjunctive or disjunctive sense and may be understood to be equivalent to “and/or.”

It will be understood that, although the terms “first,” “second,” etc. may be used herein to describe various components, these components should not be limited by these terms. These terms are only used to distinguish one component from another component. For example, a first component could be termed a second component, and vice versa without departing from the scope of the disclosure. Unless the context clearly indicates otherwise, the singular forms are intended to include the plural forms as well.

The terms “below,” “lower,” “above,” “side” (e.g., as in “sidewall”), and the like are used herein to describe one component's relationship to other component(s) illustrated in the drawings. The relative terms are intended to encompass different orientations in addition to the orientation depicted in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

It should be understood that the terms “comprise,” “include,” “have,” and the like are used to specify the presence of stated features, integers, steps, operations, components, elements, or combinations thereof, but do not preclude the presence or addition of one or more other features, integers, steps, operations, components, elements, or combinations thereof.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The following will now describe embodiments of the disclosure in conjunction with the accompanying drawings.

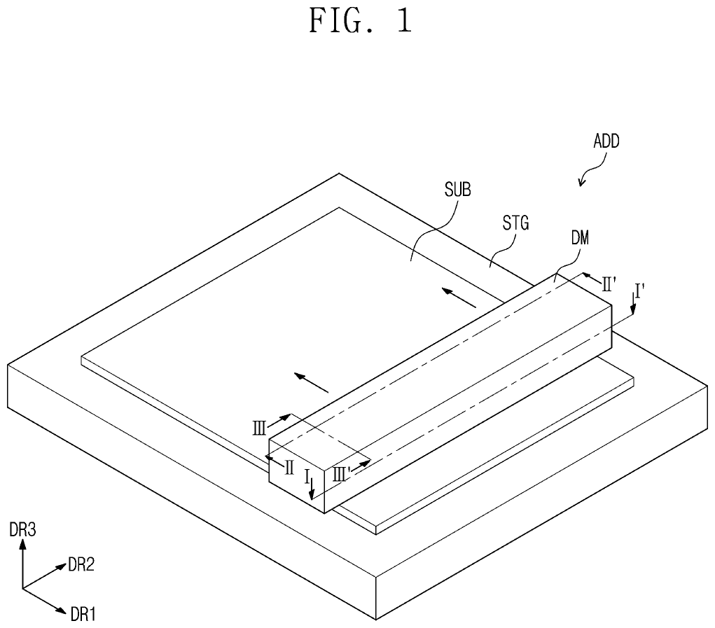

FIG. 1 is a schematic perspective view illustrating an atomic layer deposition apparatus according to an embodiment of the disclosure.

Referring to FIG. 1, an atomic layer deposition apparatus ADD according to an embodiment of the disclosure may include a stage STG and a deposition module DM disposed on the stage STG. The stage STG may have a rectangular shape having long sides that extend in a first direction DR1 and short sides that extend in a second direction DR2 intersecting the first direction DR1 in a plan view.

In the following description, a third direction DR3 may be a direction substantially perpendicular to a plane defined by the first direction DR1 and the second direction DR2. In this description, the phrase “when viewed from the top” or “in a plan view” may mean “when viewed in the third direction DR3.”

A substrate SUB may be disposed on a top surface of the stage STG. The substrate SUB may have a rectangular shape having long sides that extend in the first direction DR1 and short sides that extend in the second direction DR2 intersecting the first direction DR1 in a plan view.

The deposition module DM may be disposed on the substrate SUB. The deposition module DM may reciprocally move in the first direction DR1 and the direction opposite to the first direction DR1 on the substrate SUB. However, the disclosure is not limited thereto, and the substrate SUB may reciprocally move in the first direction DR1 and the direction opposite to the first direction DR1 while the deposition module DM is fixed. The stage STG may be implemented as a movable stage to move the substrate SUB.

The deposition module DM may have a rectangular shape having long sides that extend in the first direction DR1 and short sides that extend in the second direction DR2 in a plan view. For example, the deposition module DM may extend longer in the second direction DR2 than the first direction DR1.

The deposition module DM may be a deposition head. The deposition module DM may provide a deposition material to the substrate SUB to form a thin layer on the substrate SUB. The deposition material may be deposited in atomic layer deposition. A configuration and operation of the deposition module DM will be further described in detail below.

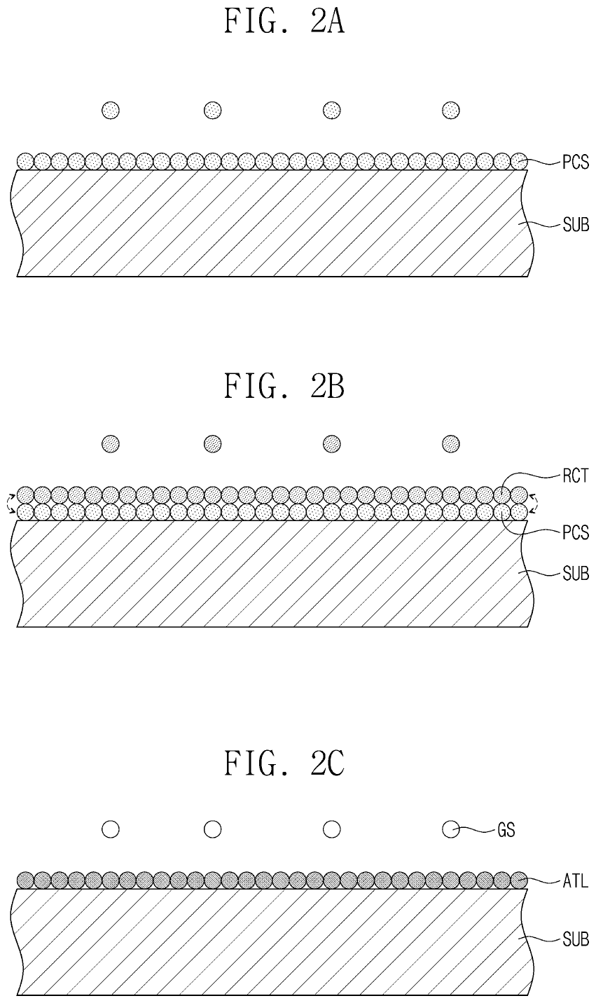

FIGS. 2A to 2C are schematic simplified cross-sectional views illustrating an atomic layer deposition method.

FIGS. 2A to 2C schematically illustrate a process in which an atomic layer deposition method is used to form a gate oxide dielectric layer according to an embodiment.

Referring to FIG. 2A, the substrate SUB may be provided with a precursor PCS in a gaseous state. The precursor PCS may be a source gas. For example, the precursor PCS may include Al(CH₃)₃ or the like. The precursor PCS may be adsorbed on the substrate SUB. For example, a 2Al(CH₃)₃ molecule may be adsorbed on the substrate SUB.

Only a single layer of the precursor PCS may be adsorbed on the substrate SUB. Even though the precursor PCS or Al(CH₃)₃ is continuously supplied, only a single layer of the precursor PCS may be stacked on the substrate SUB. The single layer of the precursor PCS stacked on the substrate SUB may be a self-limiting reaction. A remaining precursor PCS that is not adsorbed on the substrate SUB may be exhausted.

Referring to FIG. 2B, the substrate SUB may be provided with a reactant RCT in a gaseous state. The reactant RCT may be a reaction gas. For example, the reactant RCT may be H₂O or the like. The substrate SUB may be supplied with a 3H₂O molecule. The reactant RCT and the precursor PCS may undergo a chemical substitution reaction. For example, H₂O and Al(CH₃)₃ may undergo a chemical substitution reaction.

Similar to the precursor PCS, even though the reactant RCT or H₂O is continuously supplied, only a single layer may undergo an adsorption reaction and/or a substitution reaction. A remaining reactant RCT may be exhausted.

Referring to FIG. 2C, the chemical substitution reaction between the reactant RCT and the precursor PCS may form a single-layered atomic layer ATL on the substrate SUB. For example, H₂O and Al(CH₃)₃ may undergo a chemical substitution reaction to form a single-layered Al₂O₃ on the substrate SUB, and a gas GS (e.g., CH₄ or the like) that remains after the chemical substitution reaction may be exhausted.

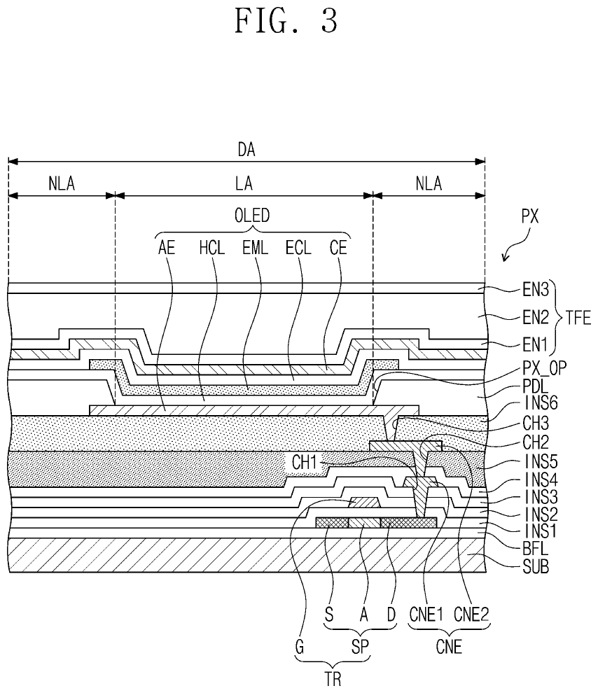

FIG. 3 is a schematic cross-sectional view illustrating a pixel including a thin layer formed using an atomic layer deposition apparatus of FIG. 1.

Referring to FIG. 3, a pixel PX may include a transistor TR and a light-emitting element OLED. The light-emitting element OLED may include a first electrode (or anode) AE, a second electrode (or cathode) CE, a hole control layer HCL, an electron control layer ECL, and an emission layer EML.

The transistor TR and the light-emitting element OLED may be disposed on the substrate SUB. Although a single transistor TR is illustrated in FIG. 3, the disclosure is not limited thereto, and the pixel PX may include at least one capacitor and multiple transistors for driving the light-emitting element OLED.

A display area DA may include an emission area LA that corresponds to a corresponding one of the pixels PX and a non-emission area NLA disposed adjacent to the emission area LA. The light-emitting element OLED may be disposed in the emission area LA.

The substrate SUB may include a flexible plastic material, such as polyimide (PI) or the like. A buffer layer BFL may be disposed on the substrate SUB, and the buffer layer BFL may be an inorganic layer.

A semiconductor pattern SP may be disposed on the buffer layer BFL. The semiconductor pattern SP may be formed by the atomic layer deposition apparatus ADD depicted in FIG. 1. The semiconductor pattern SP may include an oxide semiconductor. For example, the semiconductor pattern SP may include a transparent conductive oxide (TCO), such as indium tin oxide (ITO), indium zinc oxide (IZO), indium gallium zinc oxide (IGZO), zinc oxide (ZnO), indium oxide (In₂O₃), or the like.

The semiconductor pattern SP may include multiple regions that are distinguished based on whether a metal oxide is reduced or not. A region (or reducing region) where a metal oxide is reduced may have a conductivity greater than a conductivity of a region (or non-reducing region) where a metal oxide is not reduced. The reduced region may substantially serve as a source (electrode) S or a drain (electrode) D of a transistor TR. The non-reduced region may substantially correspond to an active (electrode) A (or channel) of a transistor TR.

The transistor TR may include a source S, an active A, and a drain D that are formed from the semiconductor pattern SP. A first dielectric layer INS1 may be disposed on the semiconductor pattern SP. A gate G of the transistor TR may be disposed on the first dielectric layer INS1. A second dielectric layer INS2 may be disposed on the gate G. A third dielectric layer INS3 may be disposed on the second dielectric layer INS2.

A connection electrode CNE may include a first connection electrode CNE1 and a second connection electrode CNE2 and electrically connect the transistor TR and the light-emitting element OLED to each other. The first connection electrode CNE1 may be disposed on the third dielectric layer INS3, and may be connected to the drain D through a first contact hole CH1 formed in the first to third dielectric layers INS1 to INS3.

A fourth dielectric layer INS4 may be disposed on the first connection electrode CNE1. A fifth dielectric layer INS5 may be disposed on the fourth dielectric layer INS4. The second connection electrode CNE2 may be disposed on the fifth dielectric layer INS5. The second connection electrode CNE2 may be connected to the first connection electrode CNE1 through a second contact hole CH2 formed in the fourth and fifth dielectric layers INS4 and INS5.

A sixth dielectric layer INS6 may be disposed on the second connection electrode CNE2. The first to sixth dielectric layers INS1 to INS6 may be inorganic layers, organic layers, the like, or a combination thereof.

The first electrode AE may be disposed on the sixth dielectric layer INS6. The first electrode AE may be connected to the second connection electrode CNE2 through a third contact hole CH3 formed in the sixth dielectric layer INS6. A pixel definition layer PDL having an opening PX_OP may be disposed on the first electrode AE and the sixth dielectric layer INS6 and expose a portion (e.g., a certain or selectable portion) of the first electrode AE.

The hole control layer HCL may be disposed on the first electrode AE and the pixel definition layer PDL. The hole control layer HCL may include a hole transport layer and a hole injection layer.

The emission layer EML may be disposed on the hole control layer HCL. The emission layer EML may be disposed on a location (or a region) that corresponds to the opening PX_OP. The emission layer EML may include an organic material, an inorganic material, the like, or a combination thereof. The emission layer EML may generate one of red light, green light, and blue light.

The electron control layer ECL may be disposed on the emission layer EML and the hole control layer HCL. The electron control layer ECL may include an electron transport layer and an electron injection layer. The second electrode CE may be disposed on the electron control layer ECL.

A thin-film encapsulation layer TFE may be disposed on the second electrode CE, covering the pixel PX. The thin-film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first and third encapsulation layers EN1 and EN3 may be each an inorganic dielectric layer, and may protect the pixel PX from moisture, oxygen, and/or the like. The second encapsulation layer EN2 may be an organic dielectric layer, and may protect the pixel PX from foreign substances such as dust particles or the like.

The first electrode AE may be supplied through the transistor TR with a first voltage, and the second electrode CE may be supplied with a second voltage less than the first voltage. Holes and electrons injected into the emission layer EML may combine with each other to produce excitons, and the light-emitting element OLED may emit light as the excitons return to ground state.

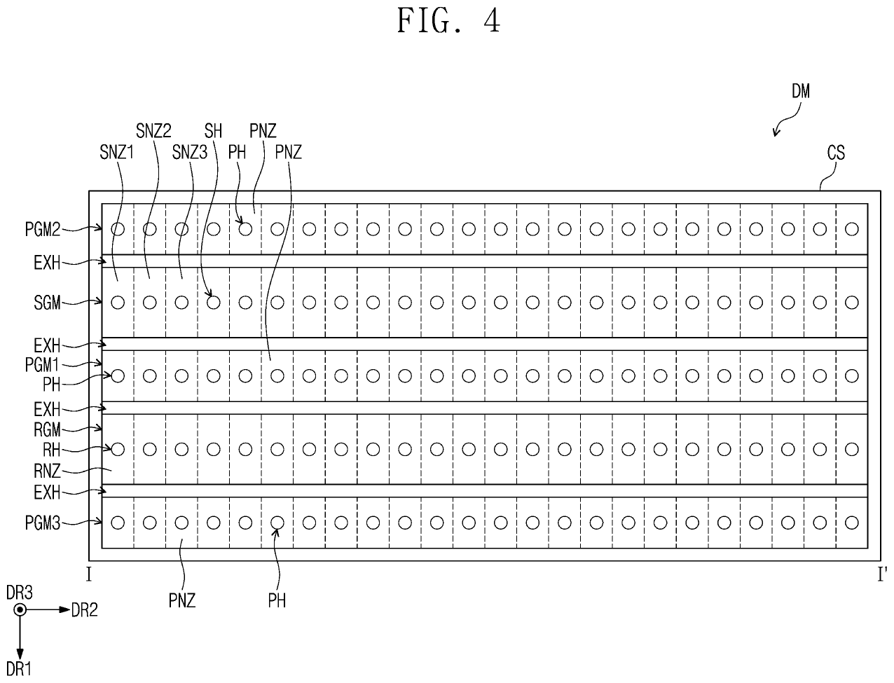

FIG. 4 is a schematic cross-sectional view taken along line I-I′ of FIG. 1.

FIG. 4 is a schematic cross-sectional view illustrating the deposition module DM taken along line I-I′ in a direction opposite to the first direction DR1. FIG. 1 shows line I-I′ illustrated as an arrow directed from top to bottom, and FIG. 4 illustrates a schematic cross-sectional view of the deposition module DM in a plan view.

Referring to FIG. 4, the deposition module DM may include a source gas supply module SGM, a reaction gas supply module RGM, a first purge gas supply module PGM1, a second purge gas supply module PGM2, a third purge gas supply module PGM3, and a casing CS. The casing CS may accommodate the source gas supply module SGM, the reaction gas supply module RGM, and the first, second, and third purge gas supply modules PGM1, PGM2, and PGM3.

Although not shown, a lower portion of the casing CS may be exposed, and the casing CS may expose lower portions of the source gas supply module SGM, the reaction gas supply module RGM, and the first, second, and third purge gas supply modules PGM1, PGM2, and PGM3.

The source gas supply module SGM may have a bar shape that extends longer in the second direction DR2 than the first direction DR1 in a plan view. The source gas supply module SGM may supply multiple different source gases onto the substrate SUB.

The source gas supply module SGM may include multiple first source gas nozzles SNZ1, multiple second source gas nozzles SNZ2, and multiple third source gas nozzles SNZ3. The source gas nozzles SNZ1, SNZ2, and SNZ3 may be arranged in the second direction DR2. A source gas injection hole SH may be defined in each of the source gas nozzles SNZ1, SNZ2, and SNZ3.

Substantially, the source gas nozzles SNZ1, SNZ2, and SNZ3 may have a single unitary configuration (or integral with each other), and may be divided from each other by multiple regions in which multiple source gas injection holes SH are formed. For example, the source gas supply module SGM may include multiple regions that are divided in the second direction DR2, the source gas injection hole SH may be correspondingly formed in each of the divided regions, and the divided regions may be the source gas nozzles SNZ1, SNZ2, and SNZ3.

The source gas nozzles SNZ1, SNZ2, and SNZ3 may include multiple first source gas nozzles SNZ1, multiple second source gas nozzles SNZ2, and multiple third source gas nozzles SNZ3. The first, second, and third source gas nozzles SNZ1, SNZ2, and SNZ3 may be sequentially and repeatedly arranged in the second direction DR2.

The first, second, and third source gas nozzles SNZ1, SNZ2, and SNZ3 may supply different source gases. For example, the first source gas nozzles SNZ1 may supply a first source gas, the second source gas nozzles SNZ2 may supply a second source gas, and the third source gas nozzles SNZ3 may supply a third source gas. The first, second, and third source gases may be supplied through the source gas injection holes SH.

The reaction gas supply module RGM may be spaced apart in the first direction DR1 from the source gas supply module SGM. The reaction gas supply module RGM may have a bar shape that extends longer in the second direction DR2 than the first direction DR1 in a plan view. The reaction gas supply module RGM may supply a reaction gas onto the substrate SUB.

The reaction gas supply module RGM may include multiple reaction gas nozzles RNZ. The reaction gas nozzles RNZ may be arranged in the second direction DR2. A reaction gas injection hole RH may be defined in each of the reaction gas nozzles RNZ. The reaction gas may be supplied through the reaction gas injection holes RH.

Substantially, the reaction gas nozzles RNZ may have a single unitary configuration (or integral with each other), and may be divided from each other by multiple regions in which multiple reaction gas injection holes RH are formed. For example, the reaction gas supply module RGM may include multiple regions that are divided in the second direction DR2, the reaction gas injection hole RH may be correspondingly formed in each of the divided regions, and the divided regions may be the reaction gas nozzles RNZ.

The first, second, and third purge gas supply modules PGM1, PGM2, and PGM3 may each have a bar shape that extends longer in the second direction DR2 than the first direction DR1 in a plan view. Each of the first, second, and third purge gas supply modules PGM1, PGM2, and PGM3 may supply a purge gas onto (or toward) the substrate SUB.

The first purge gas supply module PGM1 may be disposed between the source gas supply module SGM and the reaction gas supply module RGM. The source gas supply module SGM may be disposed between the first purge gas supply module PGM1 and the second purge gas supply module PGM2. The reaction gas supply module RGM may be disposed between the first purge gas supply module PGM1 and the third purge gas supply module PGM3.

The first, second, and third purge gas supply modules PGM1, PGM2, and PGM3 may have substantially a same configuration, and the following description will focus on the first purge gas supply module PGM1.

The first purge gas supply module PGM1 may include multiple purge gas nozzles PNZ. The purge gas nozzles PNZ may be arranged in the second direction DR2. A purge gas injection hole PH may be defined in each of the purge gas nozzles PNZ. A purge gas may be supplied through the purge gas injection holes PH.

Substantially, the purge gas nozzles PNZ may have a single unitary configuration (or integral with each other), and may be divided from each other by multiple regions in which multiple purge gas injection holes PH are formed. For example, the first purge gas supply module PGM1 may include multiple regions that are divided in the second direction DR2, the purge gas injection hole PH may be correspondingly formed in each of the divided regions, and the divided regions may be the purge gas nozzles PNZ.

Multiple exhaust holes EXH may be defined in the deposition module DM. The exhaust holes EXH may be disposed between the source gas supply module SGM and the first purge gas supply module PGM1, between the reaction gas supply module RGM and the first purge gas supply module PGM1, between the source gas supply module SGM and the second purge gas supply module PGM2, and between the reaction gas supply module RGM and the third purge gas supply module PGM3.

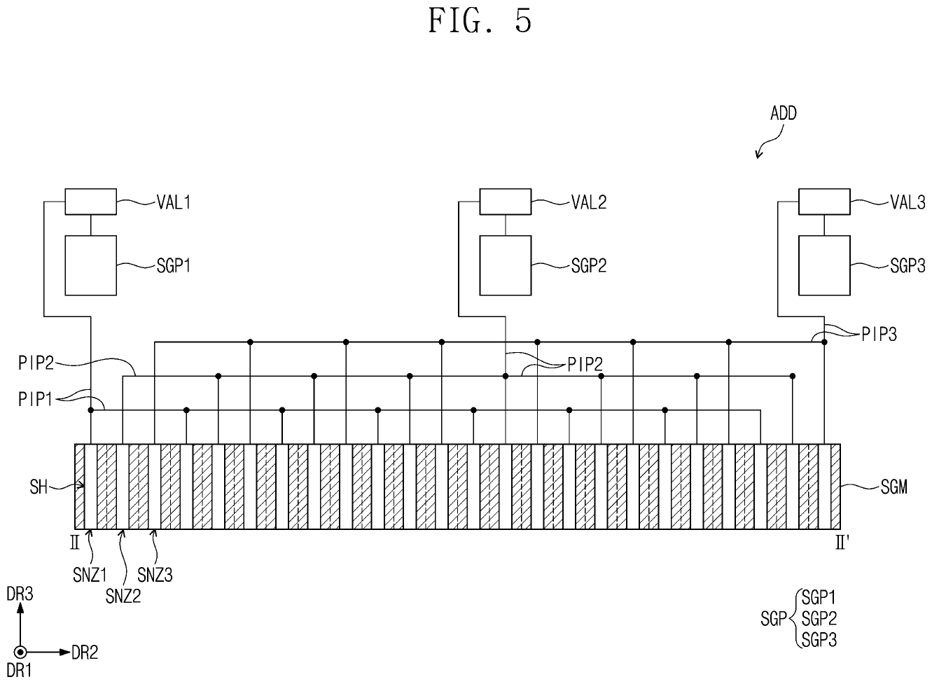

FIG. 5 is a schematic cross-sectional view taken along line II-II′ of FIG. 1.

For example, FIG. 5 illustrates a cross-section of the source gas supply module SGM disposed (or accommodated) in the casing CS, and the casing CS is omitted in FIG. 5. FIG. 5 also illustrates components disposed outside the casing CS and connected to the source gas supply module SGM.

Referring to FIG. 5, the atomic layer deposition apparatus ADD may include a source gas supply part SGP, multiple valves VAL1, VAL2, and VAL3, and multiple pipes PIP1, PIP2, and PIP3. The source gas supply part SGP may be connected to the source gas supply module SGM, and may supply the source gas supply module SGM with multiple source gases described above in FIG. 4.

The source gas supply part SGP may include a first source gas supply part SGP1, a second source gas supply part SGP2, and a third source gas supply part SGP3. The first source gas supply part SGP1 may supply a first source gas to the source gas supply module SGM. The second source gas supply part SGP2 may supply a second source gas to the source gas supply module SGM. The third source gas supply part SGP3 may supply a third source gas to the source gas supply module SGM.

The first, second, and third source gases may be the precursor PCS described above. For example, the atomic layer deposition apparatus ADD may deposit an oxide semiconductor, such as indium gallium zinc oxide (IGZO) or the like, on the substrate SUB, and the first source gas may include indium (In), the second source gas may include gallium (Ga), and the third source gas may include zinc (Zn).

The first source gas supply part SGP1 may store a first source in a liquid state. The first source gas supply part SGP1 may include a hot wire, and may supply the first source gas that is heated by the hot wire and vaporized to the source gas supply module SGM.

The second source gas supply part SGP2 may store a second source in a liquid state. The second source gas supply part SGP2 may include a hot wire, and may supply the second source gas that is heated by the hot wire and vaporized to the source gas supply module SGM.

The third source gas supply part SGP3 may store a third source in a liquid state. The third source gas supply part SGP3 may include a hot wire, and may supply the third source gas that is heated by the hot wire and vaporized to the source gas supply module SGM.

The first source gas nozzles SNZ1 may be connected to the first source gas supply part SGP1. The second source gas nozzles SNZ2 may be connected to the second source gas supply part SGP2. The third source gas nozzles SNZ3 may be connected to the third source gas supply part SGP3.

The first, second, and third source gas supply parts SGP1, SGP2, and SGP3 may be connected to the first, second, and third source gas nozzles SNZ1, SNZ2, and SNZ3 through the valves VAL1, VAL2, and VAL3 and the pipes PIP1, PIP2, and PIP3.

The valves VAL1, VAL2, and VAL3 may include a first valve VAL1, a second valve VAL2, and a third valve VAL3. The pipes PIP1, PIP2, and PIP3 may include a first pipe PIP1, a second pipe PIP2, and a third pipe PIP3.

The first valve VAL1 may be connected to the first source gas supply part SGP1 and the first source gas nozzles SNZ1. The first valve VAL1 may be connected through the first pipe PIP1 to the first source gas nozzles SNZ1. Therefore, the first source gas supply part SGP1 and the first source gas nozzles SNZ1 may be connected to each other through the first valve VAL1 and the first pipe PIP1. The first valve VAL1 may be opened and closed to control the first source gas supplied to the first source gas nozzles SNZ1.

The second valve VAL2 may be connected to the second source gas supply part SGP2 and the second source gas nozzles SNZ2. The second valve VAL2 may be connected through the second pipe PIP2 to the second source gas nozzles SNZ2. Therefore, the second source gas supply part SGP2 and the second source gas nozzles SNZ2 may be connected to each other through the second valve VAL2 and the second pipe PIP2. The second valve VAL2 may be opened and closed to control the second source gas supplied to the second source gas nozzles SNZ2.

The third valve VAL3 may be connected to the third source gas supply part SGP3 and the third source gas nozzles SNZ3. The third valve VAL3 may be connected through the third pipe PIP3 to the third source gas nozzles SNZ3. Therefore, the third source gas supply part SGP3 and the third source gas nozzles SNZ3 may be connected to each other through the third valve VAL3 and the third pipe PIP3. The third valve VAL3 may be opened and closed to control the third source gas supplied to the third source gas nozzles SNZ3.

As described above, the first, second, and third source gas nozzles SNZ1, SNZ2, and SNZ3 may be sequentially and repeatedly arranged in the second direction DR2. The source gas injection holes SH defined in the first, second, and third source gas nozzles SNZ1, SNZ2, and SNZ3 may extend in the third direction DR3 and be arranged in the second direction DR2.

With such configuration, the source gas supply module SGM may receive and supply the first, second, and third source gases onto the substrate SUB.

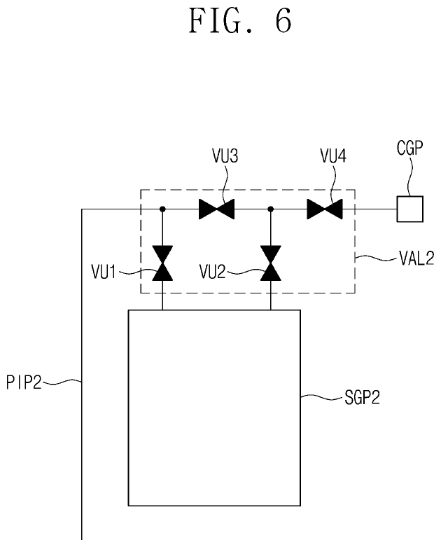

FIG. 6 is a schematic diagram illustrating a second valve connected to a second source gas supply part of FIG. 5.

As the first valve VAL1, the second valve VAL2, and the third valve VAL3 have substantially a same configuration and operate identically to each other, the following will focus on the configuration of the second valve VAL2 and will briefly describe configurations of the first and third valves VAL1 and VAL3.

Referring to FIG. 6, the second valve VAL2 may include a first valve part VU1, a second valve part VU2, a third valve part VU3, and a fourth valve part VU4. An end of the first valve part VU1 and an end of the second valve part VU2 may be connected to a corresponding second source gas supply part SPG2 among the first, second, and third source gas supply parts SGP1, SPG2, and SPG3 of FIG. 5.

Another end of the second valve part VU2 may be connected to an end of the third valve part VU3, and another end of the first valve part VU1 may be connected to another end of the third valve part VU3. An end of the fourth valve part VU4 may be connected to a carrier gas supply part CGP, and another end of the fourth valve part VU4 may be connected to the end of the third valve part VU3.

The carrier gas supply part CGP may supply a carrier gas to the fourth valve part VU4. The carrier gas may include an inert gas, such as argon (Ar), nitrogen (N₂), helium (He), the like, or a mixture thereof.

The another end of the third valve part VU3 may be connected to corresponding second source gas nozzles SNZ2 among the first, second, and third source gas nozzles SNZ1, SNZ2, and SNZ3. The third valve part VU3 may be connected through the second pipe PIP2 to the second source gas nozzles SNZ2.

Although not shown, similar to the second valve VAL2, each of the first and third valves VAL1 and VAL3 may include a first valve part VU1, a second valve part VU2, a third valve part VU3, and a fourth valve part VU4. The first, second, third, and fourth valve parts VU1, VU2, VU3, and VU4 of each of the first valve VAL1 and the third valve VAL3 and the first, second, third, and fourth valve parts VU1, VU2, VU3, and VU4 of the second valve VAL2 may have a same configuration (e.g., a same connection configuration).

The first, second, third, and fourth valve parts VU1, VU2, VU3, and VU4 of each of the first valve VAL1 and the third valve VAL3 may be connected to a corresponding one of the first and third source gas supply parts SGP1 and SGP3 and corresponding ones of the first and third source gas nozzles SNZ1 and SNZ3.

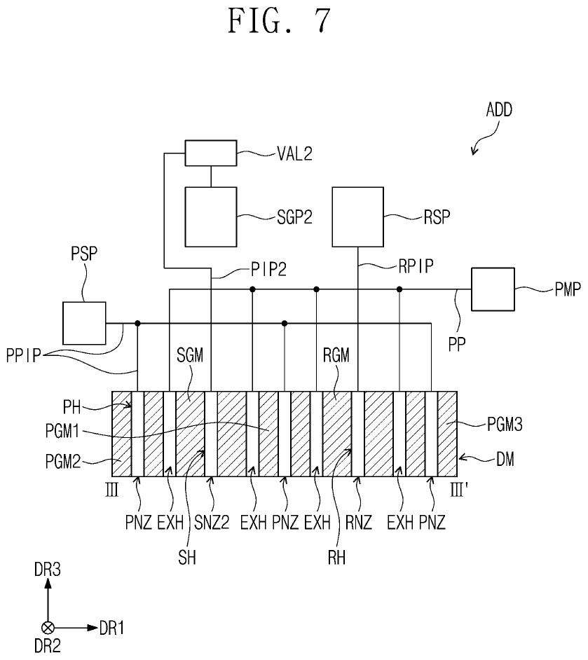

FIG. 7 is a schematic cross-sectional view taken along line III-III′ of FIG. 1.

FIG. 7 schematically illustrates cross-sections of the source gas supply module SGM, the reaction gas supply module RGM, and the first, second, and third purge gas supply modules PGM1, PGM2, and PGM3 that are disposed in the casing CS, and the casing CS is omitted in FIG. 7.

FIG. 7 also illustrates multiple components disposed outside the casing CS and connected to the source gas supply module SGM, the reaction gas supply module RGM, and the first, second, and third purge gas supply modules PGM1, PGM2, and PGM3. For example, FIG. 7 shows the second source gas supply part SGP2 among the first, second, and third source gas supply parts SGP1, SGP2, and SGP3 of FIG. 5.

Referring to FIG. 7, as described above, the second source gas supply part SGP2 may be connected to the second source gas nozzles SNZ2. The reaction gas injection holes RH and the purge gas injection holes PH may extend in the third direction DR3. The source gas injection holes SH and the reaction gas injection holes RH may be correspondingly disposed between the purge gas injection holes PH. The exhaust holes EXH may be disposed between the source and reaction gas injection holes SH and RH and the purge gas injection holes PH.

The atomic layer deposition apparatus ADD may include a reaction gas supply part RSP, a purge gas supply part PSP, a pumping module PMP, a reaction gas pipe RPIP, a purge gas pipe PPIP, and a pumping pipe PP.

The reaction gas supply part RSP may supply a reaction gas to the reaction gas supply module RGM. The reaction gas supply module RGM may be connected through the reaction gas pipe RPIP to the reaction gas supply part RSP, and may be supplied with the reaction gas. The reaction gas may be the reactant RCT. For example, the reaction gas may include H₂O, O₂, O₃, the like, or a combination thereof.

The reaction gas supply part RSP may be connected through the reaction gas pipe RPIP to the reaction gas nozzle RNZ. The reaction gas supply part RSP may supply the reaction gas to the reaction gas nozzle RNZ through the reaction gas pipe RPIP.

Referring to FIG. 7, in a cross-sectional structure, it is illustrated that a single reaction gas nozzle RNZ is connected to the reaction gas supply part RSP, but the disclosure is not limited thereto, and multiple reaction gas nozzles RNZ (see, e.g., FIG. 5) may be connected through the reaction gas pipe RPIP to the reaction gas supply part RSP.

In accordance with the structure described above, the reaction gas supply module RGM may receive (from the reaction gas supply part RSP) and supply the reaction gas onto the substrate SUB.

The purge gas supply part PSP may supply a purge gas to the first, second, and third purge gas supply modules PGM1, PGM2, and PGM3. The first, second, and third purge gas supply modules PGM1, PGM2, and PGM3 may be connected through the purge gas pipe PPIP to the purge gas supply part PSP, and may be supplied with the purge gas. The purge gas and the carrier gas may include a same gas. For example, the purge gas may include an inert gas, such as argon (Ar), nitrogen (N₂), helium (He), the like, or a mixture of two or more thereof.

The purge gas supply part PSP may be connected through the purge gas pipe PPIP to the purge gas nozzles PNZ. The purge gas supply part PSP may supply the purge gas to the purge gas nozzles PNZ through the purge gas pipe PPIP.

Referring to FIG. 7, in a cross-sectional structure, it is illustrated that a single purge gas nozzle PNZ of each of the first, second, and third purge gas supply modules PGM1, PGM2, and PGM3 is connected to the purge gas supply part PSP, but the disclosure is not limited thereto, and multiple purge gas nozzles PNZ of each of the first, second, and third purge gas supply modules PGM1, PGM2, and PGM3 (see, e.g., FIG. 5) may be connected through the purge gas pipe PPIP to the purge gas supply part PSP

The pumping module PMP may be connected to the exhaust holes EXH, and may provide an exhaust pressure to the exhaust holes EXH. The pumping module PMP may be connected through the pumping pipe PP to the exhaust holes EXH. The pumping module PMP may provide the exhaust pressure to the exhaust holes EXH through the pumping pipe PP. The exhaust pressure may discharge gases remaining in a process chamber through the exhaust holes EXH and the pumping pipe PP.

In accordance with the structure described above, the first, second, and third purge gas supply modules PGM1, PGM2, and PGM3 may receive (from the purge gas supply part PSP) and supply the purge gas onto the substrate SUB.

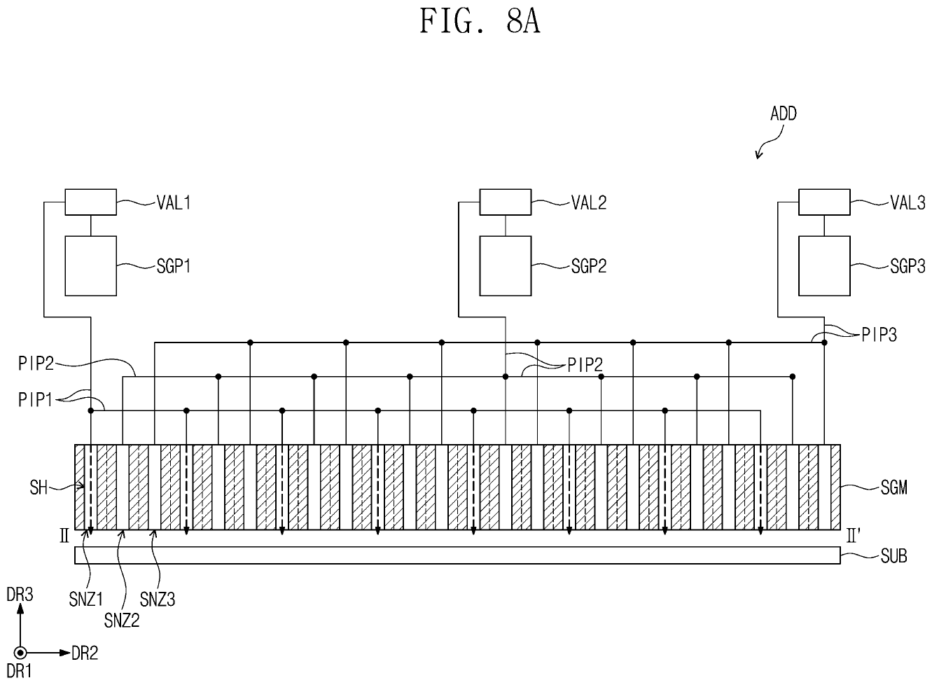

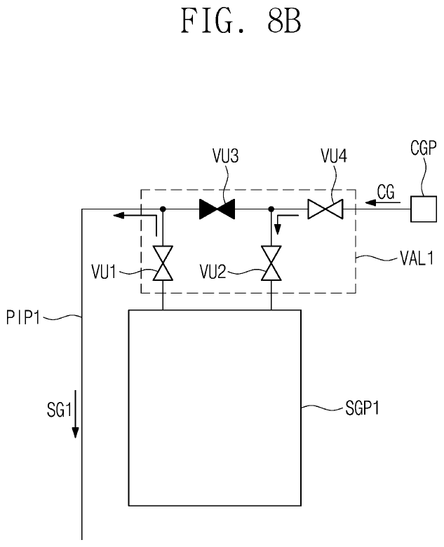

FIG. 8A is schematic cross-sectional view illustrating a process in which a substrate is supplied with a first source gas. FIG. 8B is a schematic diagram illustrating a process in which a substrate is supplied with a first source gas.

FIG. 8A illustrates a cross-section that corresponds to a cross-sectional view of FIG. 5.

Referring to FIGS. 8A and 8B, the first valve VAL1 may be opened, and the second valve VAL2 and the third valve VAL3 may be closed. The first source gas supply part SGP1 may supply a first source gas SG1 to the source gas supply module SGM through the opened first valve VAL1 and the first pipe PIP1.

The first source gas SG1 may be supplied to the first source gas nozzles SNZ1 through the first valve VAL1 and the first pipe PIP1. The first source gas SG1 may be supplied through the first source gas nozzles SNZ1 onto the substrate SUB. Therefore, the first source gas SG1 may be deposited on the substrate SUB.

In case that the first valve VAL1 is opened, the first, second, and fourth valve parts VU1, VU2, and VU4 may be opened, and the third valve part VU3 may be closed. The carrier gas supply part CGP may supply a carrier gas CG to the fourth valve part VU4. The carrier gas CG may be introduced into the first source gas supply part SGP1 through the opened fourth valve part VU4 and the opened second valve part VU2. After the carrier gas CG is introduced into the first source gas supply part SGP1, the carrier gas CG may be provided through the opened first valve part VU1 to the first pipe PIP1.

The first source gas SG1, which is vaporized in the first source gas supply part SGP1, may have a small mobility. The carrier gas CG may be supplied into the first source gas supply part SGP1 through the fourth valve part VU4 and the second valve part VU2, and may be discharged through the first valve part VU1 and supplied to the first pipe PIP1.

A gas flow (or air current) formed by the carrier gas CG may increase a mobility of the first source gas SG1. The carrier gas CG may facilitate a supply of the first source gas SG1 to the first source gas nozzles SNZ1.

In case that the second valve VAL2 and the third valve VAL3 are closed, the first to fourth valve parts VU1 to VU4 of each of the second and third valves VAL2 and VAL3 may all be closed.

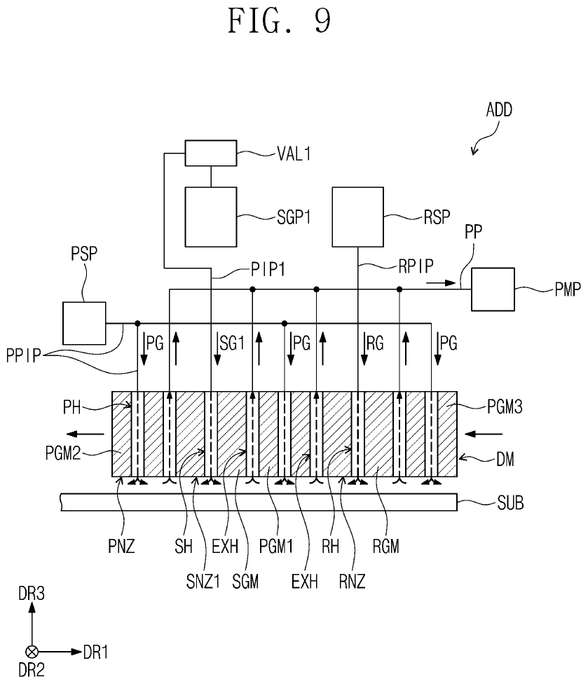

FIG. 9 is a schematic diagram illustrating a process in which a substrate is supplied with a first source gas, a reaction gas, and a purge gas.

FIG. 9 schematically illustrates a cross-section that corresponds to a cross-sectional view of FIG. 7. FIG. 9 also illustrates the first source gas supply part SGP1 and the first valve VAL1 in accordance with a deposition sequence.

Referring to FIG. 9, as described in FIGS. 8A and 8B, the first valve VAL1 may be opened to provide the first source gas SG1 onto the substrate SUB. The deposition module DM may move in a direction opposite to the first direction DR1. The deposition module DM may provide the first source gas SG1 onto the substrate SUB, while moving from rightmost side of the substate SUB toward leftmost side of the substrate SUB. In another embodiment, the deposition module DM may provide the first source gas SG1 onto the substrate SUB, while moving from leftmost side of the substate SUB toward rightmost side of the substrate SUB.

The reaction gas supply part RSP may supply a reaction gas RG to the reaction gas supply module RGM through the reaction gas pipe RPIP. The reaction gas RG may be supplied through the reaction gas pipe RPIP to the reaction gas nozzles RNZ. The reaction gas RG may be supplied through the reaction gas nozzles RNZ onto the substrate SUB.

The reaction gas RG may be provided on the substrate SUB, and may react with the first source gas SG1. In case that the first source gas SG1 includes indium (In), the first source gas SG1 and the reaction gas RG may react to form indium oxide (InOₓ) on the substrate SUB.

The purge gas supply part PSP may supply a purge gas PG through the purge gas pipe PPIP to the first, second, and third purge gas supply modules PGM1, PGM2, and PGM3. The purge gas PG may be supplied through the purge gas pipe PPIP to the purge gas nozzles PNZ. The purge gas PG may be supplied through the purge gas nozzles PNZ onto the substrate SUB.

The purge gas PG may force the first source gas SG1 to be supplied to a location (or a region) below the source gas supply module SGM and prevent the first source gas SG1 from diffusing toward a different location (or a different region). The purge gas PG may force the reaction gas RG to be supplied to a location (or a region) below the reaction gas supply module RGM and prevent the reaction gas RG from diffusing toward a different location (or a different region).

The purge gas PG may spatially separate a region of which the first source gas SG1 is supplied and another region of which the reaction gas RG is supplied. While the purge gas PG forces the first source gas SG1 and the reaction gas RG to be supplied to designated regions (e.g., the region of which the first source gas SG1 is injected and the another region of which the reaction gas RG is supplied), a residual first source gas SG1 and a residual reaction gas RG may be exhausted through the exhaust holes EXH adjacent to the gas injection holes SH and the reaction gas injection holes RH. The pumping module PMP may provide an exhaust pressure to the exhaust holes EXH through the pumping pipe PP, and the residual first source gas SG1 and the residual reaction gas RG may be exhausted through the exhaust holes EXH.

While the deposition module DM moves from rightmost side of the substate SUB toward leftmost side of the substrate SUB or from leftmost side of the substrate SUB toward rightmost side of the substrate SUB, the first source gas SG1 may be first provided on the substrate SUB, and successively the reaction gas RG may be provided on the substrate SUB. The first source gas SG1 may be deposited on the substrate SUB, the reaction gas RG may be deposited on the substrate SUB, and a first atomic layer (e.g., indium oxide (InOₓ)) may be formed on the substrate SUB.

A process of depositing the first source gas SG1 and the reaction gas RG may be repeatedly performed to form the first atomic layer to a thickness (e.g., a desired thickness). For example, while the deposition module DM reciprocally moves in the first direction DR1 and the direction opposite to the first direction DR1, the first atomic layer may be repeatedly deposited on the substrate SUB.

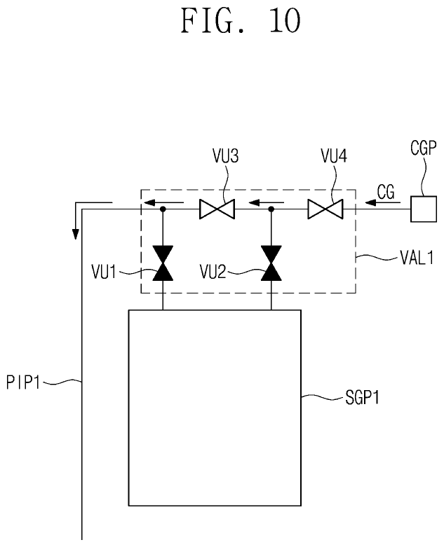

FIG. 10 is a schematic diagram illustrating an operation of a first valve after a first source gas is deposited on a substrate.

Referring to FIG. 10, the first source gas SG1 may be provided on a top surface (e.g., an entire top surface) of the substrate SUB, and the supply of the first source gas SG1 may be interrupted. In case that the supply of the first source gas SG1 is interrupted, the first valve part VU1 and the second valve part VU2 may be closed, and the third valve part VU3 and the fourth valve part VU4 may be opened.

Even in case that the supply of the first source gas SG1 is interrupted, the first source gas SG1 may remain in the first pipe PIP1 and the first source gas nozzles SNZ1. To remove the first source gas SG1 remaining in the first pipe PIP1 and the first source gas nozzles SNZ1, the carrier gas CG may be supplied at a time (e.g., a certain or selectable time) through the third valve part VU3 and the fourth valve part VU4 to the first pipe PIP1 and the first source gas nozzles SNZ1.

The carrier gas CG may discharge (or exhaust or purge) the first source gas SG1 remaining in the first pipe PIP1 and the first source gas nozzles SNZ1, and the first source gas SG1 may be exhausted through the exhaust holes EXH. After the first source gas SG1 is exhausted, the third and fourth valve parts VU3 and VU4 may be closed to close the first valve VAL1.

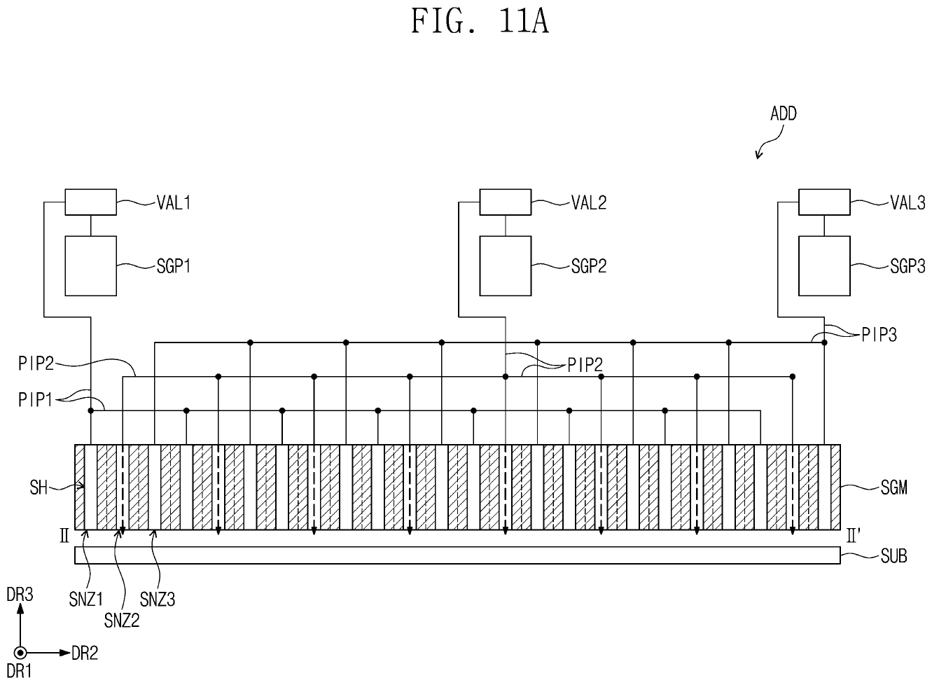

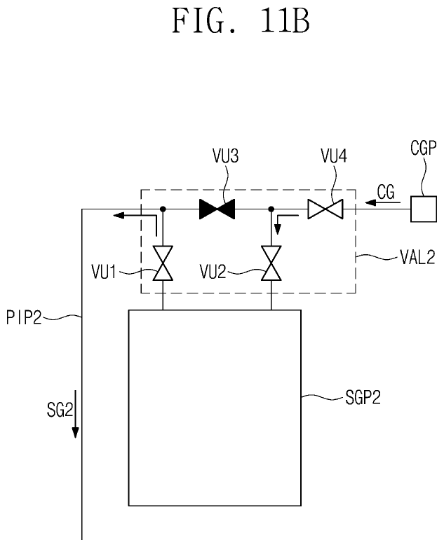

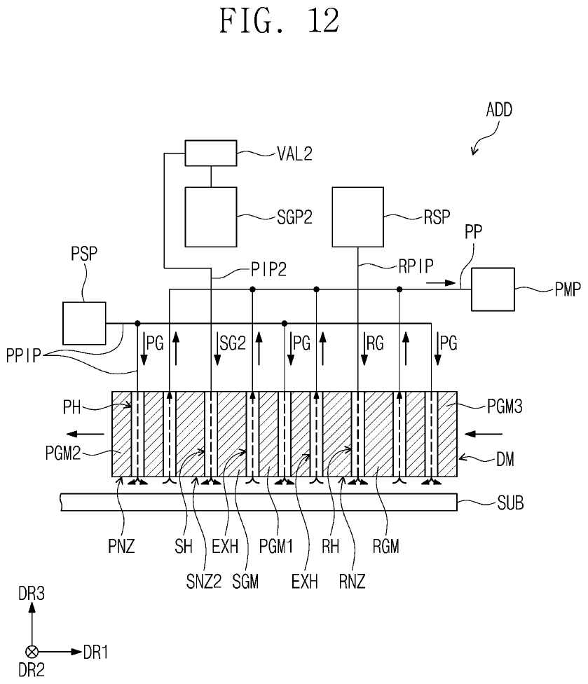

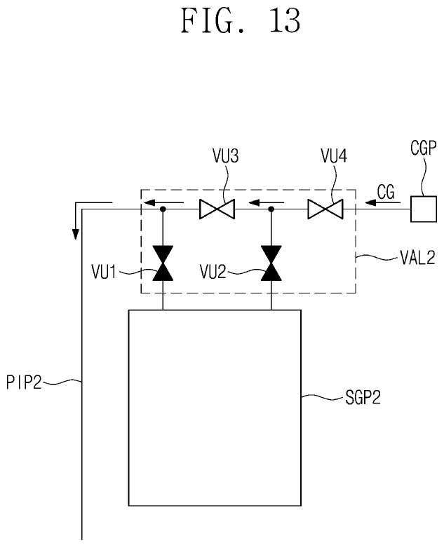

FIG. 11A is a schematic cross-sectional view illustrating a process in which a substrate is supplied with a second source gas. FIG. 11B is a schematic diagram illustrating a process in which a substrate is supplied with a second source gas. FIG. 12 is a schematic diagram illustrating a process in which a substrate is supplied with a second source gas, a reaction gas, and a purge gas. FIG. 13 is a schematic diagram illustrating an operation of a second valve after a second source gas is deposited on a substrate.

The following description will focus on processes depicted in FIGS. 11A, 111B, 12, and 13 different from those discussed in FIGS. 8A, 8B, 9, and 10.

FIG. 12 schematically illustrates the second source gas supply part SGP2 and the second valve VAL2 in accordance with a deposition sequence.

Referring to FIGS. 11A and 11B, the second valve VAL2 may be opened, and the first valve VAL1 and the third valve VAL3 may be closed. The second source gas supply part SGP2 may supply a second source gas SG2 to the second source gas nozzles SNZ2 of the source gas supply module SGM through the second valve VAL2 and the second pipe PIP2. The second source gas SG2 may be supplied through the second source gas nozzles SNZ2 onto the substrate SUB.

In case that the second valve VAL2 is opened, the first, second, and fourth valve parts VU1, VU2, and VU4 of the second valve VAL2 may be opened, and the third valve part VU3 of the second valve VAL2 may be closed. The carrier gas CG may be supplied into the second source gas supply part SGP2 through the fourth valve part VU4 and the second valve part VU2, and may be discharged through the first valve part VU1 and supplied to the second pipe PIP2. The carrier gas CG may facilitate a supply of the second source gas SG2 to the second source gas nozzles SNZ2.

In case that the first valve VAL1 and the third valve VAL3 are closed, the first to fourth valve parts VU1 to VU4 of each of the first and third valves VAL1 and VAL3 may all be closed.

Referring to FIG. 12, the second valve VAL2 may be opened to provide the second source gas SG2 onto the substrate SUB. The deposition module DM may provide the second source gas SG2 onto the substrate SUB, while moving from rightmost side of the substrate SUB toward leftmost side of the substrate SUB. In another embodiment, the deposition module DM may provide the second source gas SG2 onto the substrate SUB, while moving from leftmost side of the substrate SUB toward rightmost side of the substrate SUB.

The reaction gas supply part RSP may supply the reaction gas RG to the reaction gas nozzles RNZ of the reaction gas supply module RGM through the reaction gas pipe RPIP. The reaction gas RG may be supplied through the reaction gas nozzles RNZ onto the substrate SUB.

The reaction gas RG may be provided on the substrate SUB, and may react with the second source gas SG2. In case that the second source gas SG2 includes gallium (Ga), the second source gas SG2 and the reaction gas RG may react to form gallium oxide (GaOₓ) on the substrate SUB.

The purge gas supply part PSP may supply the purge gas PG to the purge gas nozzles PNZ through the purge gas pipe PPIP. The purge gas PG may be supplied through the purge gas nozzles PNZ onto the substrate SUB. A function of the purge gas PG is described in detail above, and a description of the function of the purge gas PG will be omitted.

While the deposition module DM moves from rightmost side of the substrate SUB toward leftmost side of the substrate SUB or from leftmost side of the substrate toward rightmost side of the substrate SUB, the second source gas SG2 may be first provided on the substrate SUB, and successively the reaction gas RG may be provided on the substrate SUB. The second source gas SG2 may be deposited on the substrate SUB, the reaction gas RG may be deposited on the substrate SUB, and a second atomic layer (e.g., gallium oxide (GaOₓ)) may be formed on the substrate SUB.

A process of depositing the second source gas SG2 and successively depositing the reaction gas RG may be repeatedly performed to form the second atomic layer to a thickness (e.g., a desired thickness). For example, while the deposition module DM reciprocally moves in the first direction DR1 and the direction opposite to the first direction DR1, the second atomic layer may be repeatedly deposited on the substrate SUB.

Referring to FIG. 13, the second source gas SG2 may be provided on a top surface (e.g., an entire top surface) of the substrate SUB, and the supply of the second source gas SG2 may be interrupted. In case that the supply of the second source gas SG2 is interrupted, the first valve part VU1 and the second valve part VU2 of the second valve VAL2 may be closed, and the third valve part VU3 and the fourth valve part VU4 of the second valve VAL2 may be opened.

The carrier gas CG may be supplied through the third and fourth valve parts VU3 and VU4 to the second pipe PIP2 and the second source gas nozzles SNZ2, which may discharge the second source gas SG2 remaining in the second pipe PIP2 and the second source gas nozzles SNZ2. After the second source gas SG2 is discharged, even the third and fourth valve parts VU3 and VU4 of the second valve VAL2 may be closed to close the second valve VAL2.

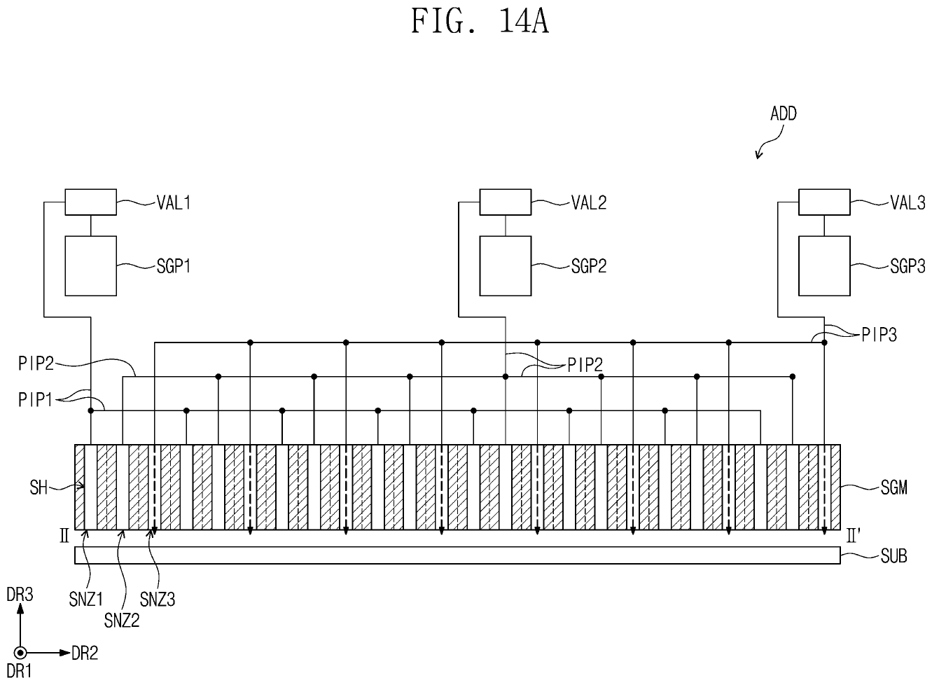

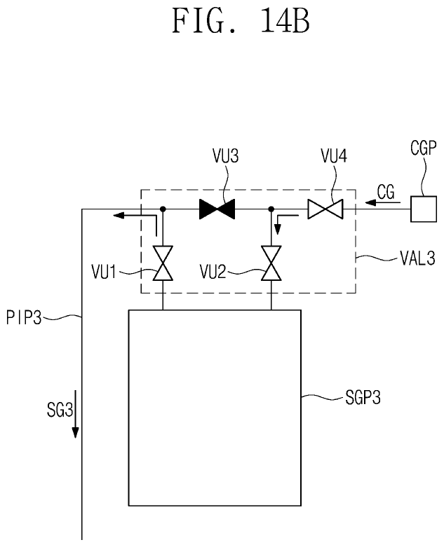

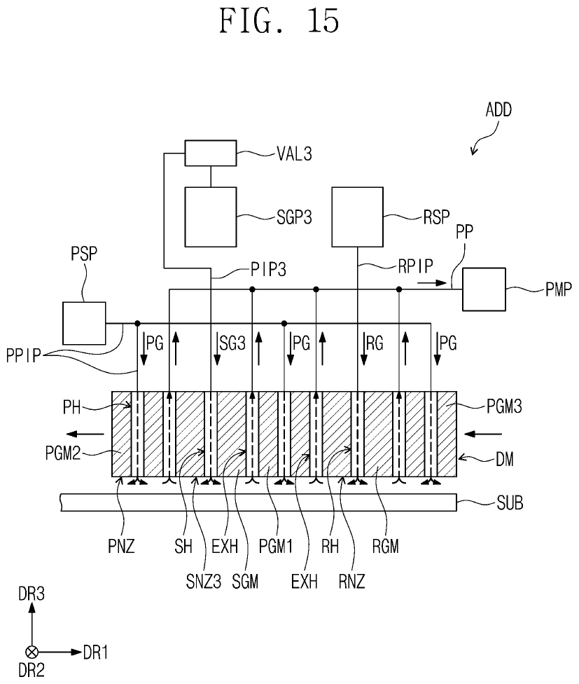

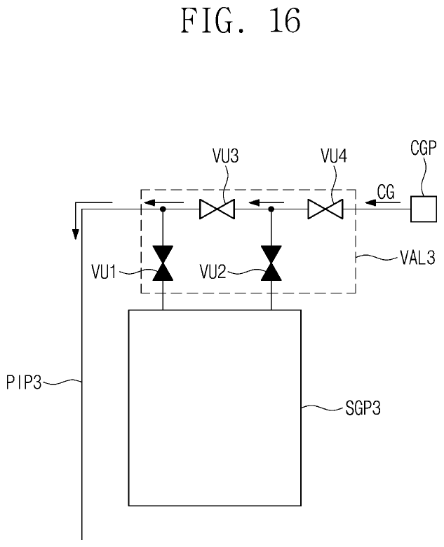

FIG. 14A is a schematic cross-sectional view illustrating a process in which a substrate is supplied with a third source gas. FIG. 14B is a schematic diagram illustrating a process in which a substrate is supplied with a third source gas. FIG. 15 is a schematic diagram illustrating a process in which a substrate is supplied with a third source gas, a reaction gas, and a purge gas. FIG. 16 is a schematic diagram illustrating an operation of a third valve after a third source gas is deposited on a substrate.

The following description will focus on processes depicted in FIGS. 14A, 14B, 15, and 16 different from those discussed in FIGS. 8A, 8B, 9, and 10.

FIG. 15 schematically illustrates the third source gas supply part SGP3 and the third valve VAL3 in accordance with a deposition sequence.

Referring to FIGS. 14A and 14B, the third valve VAL3 may be opened, and the first valve VAL1 and the second valve VAL2 may be closed. For example, the first, second, and third valves VAL1, VAL2, and VAL3 may be sequentially opened, and in case that one of the first, second, and third valves VAL1, VAL2, and VAL3 is opened, other two of the first, second, and third valves VAL1, VAL2, and VAL3 may be closed.

The third source gas supply part SGP3 may supply a third source gas SG3 to the third source gas nozzles SNZ3 of the source gas supply module SGM through the third valve VAL3 and the third pipe PIP3. The third source gas SG3 may be supplied through the third source gas nozzles SNZ3 onto the substrate SUB.

In case that the third valve VAL3 is opened, the first, second, and fourth valve parts VU1, VU2, and VU4 of the third valve VAL3 may be opened, and the third valve part VU3 of the third valve VAL3 may be closed. The carrier gas CG may be supplied into the second source gas supply part SGP2 through the fourth valve part VU4 and the second valve part VU2, and may be discharged through the first valve part VU1 and supplied to the third pipe PIP3. The carrier gas CG may facilitate a supply of the third source gas SG3 to the third source gas nozzles SNZ3.

In case that the first valve VAL1 and the second valve VAL2 are closed, the first to fourth valve parts VU1 to VU4 of each of the first and second valves VAL1 and VAL2 may all be closed.

Referring to FIG. 15, the deposition module DM may provide the third source gas SG3 onto the substrate SUB, while moving from rightmost side of the substate SUB toward leftmost side of the substrate SUB. In another embodiment deposition module DM may provide the third source gas SG3 onto the substrate SUB, from leftmost side of the substrate SUB toward rightmost side of the substrate SUB. The reaction gas supply part RSP may supply the reaction gas RG to the reaction gas nozzles RNZ. The reaction gas RG may be supplied through the reaction gas nozzles RNZ onto the substrate SUB.

The reaction gas RG may be provided on the substrate SUB, and may react with the third source gas SG3. In case that the third source gas SG3 includes zinc (Zn), the third source gas SG3 and the reaction gas RG may react to form zinc oxide (ZnO) on the substrate SUB. A process of depositing the third source gas SG3 and depositing the reaction gas RG may form an oxide semiconductor or indium gallium zinc oxide (IGZO) on the substrate SUB.

The purge gas supply part PSP may supply the purge gas PG to the purge gas nozzles PNZ, and the purge gas PG may be supplied through the purge gas nozzles PNZ onto the substrate SUB.

While the deposition module DM moves from rightmost side of the substrate SUB toward leftmost side of the substrate SUB or from leftmost side of the substrate toward rightmost side of the substrate SUB, the third source gas SG3 may be first provided on the substrate SUB, and successively the reaction gas RG may be provided on the substrate SUB. Therefore, the third source gas SG3 may be deposited on the substrate SUB, the reaction gas RG may be deposited on the substrate SUB, and a third atomic layer (e.g., zinc oxide (ZnO)) may be formed on the substrate SUB. A process of depositing the third source gas SG3 and successively depositing the reaction gas RG may be repeatedly performed to form the third atomic layer to a thickness (e.g., a desired thickness).

In case that the thin layer to be deposited on the substrate SUB includes indium gallium zinc oxide (IGZO), a ratio (e.g., a certain or selectable ratio) may be provided between constituents of the indium gallium zinc oxide (IGZO). For example, indium oxide (InOₓ), gallium oxide (GaOₓ), and zinc oxide (ZnO) may be formed at a ratio of about 6:3:1 on the substrate SUB. In forming a thin layer, the number of times of the processes for forming the first atomic layer, the second atomic layer, and the third atomic layer may be set at a ratio of about 6:3:1.

Referring to FIG. 16, in case that the third source gas SG3 is provided on a top surface (e.g., an entire top surface) of the substrate SUB and the supply of the third source gas SG3 is interrupted, the first valve part VU1 and the second valve part VU2 of the third valve VAL3 may be closed, and the third valve part VU3 and the fourth valve part VU4 of the third valve VAL3 may be opened.

The carrier gas CG may be supplied through the third and fourth valve parts VU3 and VU4 to the third pipe PIP3 and the third source gas nozzles SNZ3, which may discharge the third source gas SG3 remaining in the third pipe PIP3 and the third source gas nozzles SNZ3. After the third source gas SG3 is discharged, the third and fourth valve parts VU3 and VU4 of the third valve VAL3 may be closed to close the third valve VAL3.

In an embodiment of the disclosure, in a single source gas supply module SGM, the first, second, and third source gases SG1, SG2, and SG3 may be provided through the first, second, and third source gas nozzles SNZ1, SNZ2, and SNZ3 onto the substrate SUB and multiple thin layers (e.g., the first, second, and third atomic layers) may be formed on the substrate SUB.

In an embodiment of the disclosure, separate three source gas supply modules to supply the first, second, and third source gases SG1, SG2, and SG3 may be unnecessary. Therefore, as multiple source gas supply modules are not used, the atomic layer deposition apparatus ADD may become small in size and a process may become simplified.

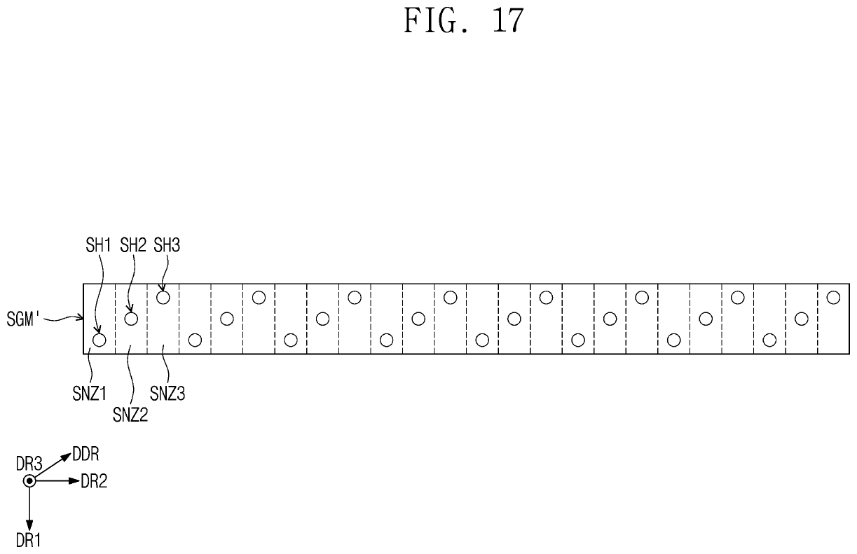

FIG. 17 is a schematic diagram illustrating a source gas supply module according to an embodiment of the disclosure.

For example, FIG. 17 illustrates a cross-section of a source gas supply module SGM′, corresponding to FIG. 4.

The following description will focus on a configuration of the source gas supply module SGM′ of FIG. 17 different from that of the source gas supply module SGM depicted in FIG. 4.

Referring to FIG. 17, the source gas supply module SGM′ may include the first, second, and third source gas nozzles SNZ1, SNZ2, and SNZ3 that are sequentially and repeatedly disposed in the second direction DR2. The first source gas injection hole SH1 may be defined in each of the first source gas nozzles SNZ1, the second source gas injection hole SH2 may be defined in each of the second source gas nozzles SNZ2, and the third source gas injection hole SH3 may be defined in each of the third source gas nozzles SNZ3.

Neighboring (or adjacent) three source gas injection holes, or the first, second, and third source gas injection holes SH1, SH2, and SH3, may be arranged in a diagonal direction DDR. For example, the first, second, and third source gas injection holes SH1, SH2, and SH3 may be repeatedly arranged in the diagonal direction DDR in the sequence of the first source gas injection hole SH1, the second source gas injection hole SH2, and the third source gas injection hole SH3. The diagonal direction DDR may be a direction that intersects the first and second directions DR1 and DR2.

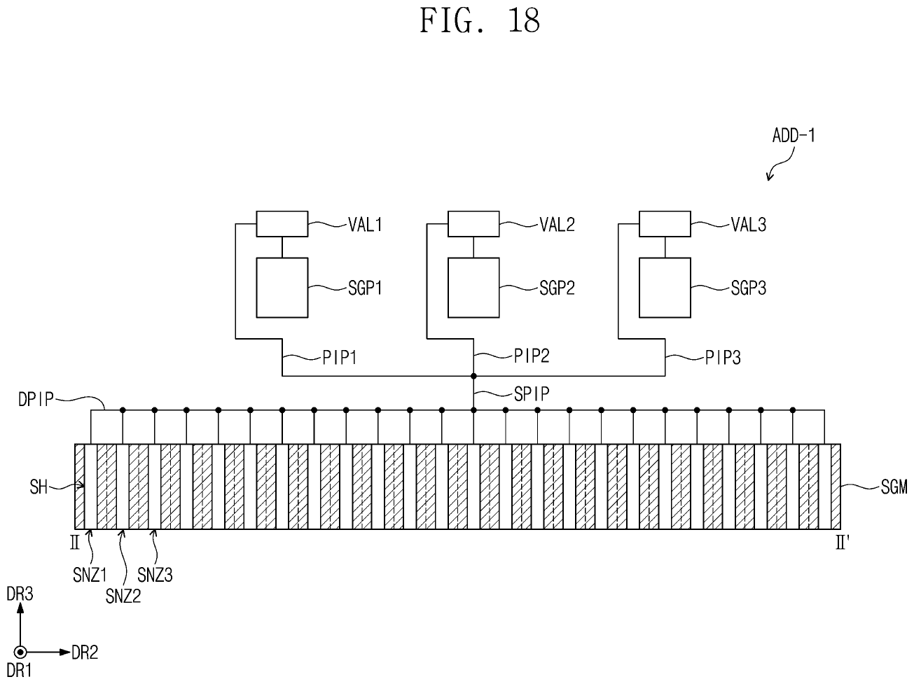

FIG. 18 is a schematic diagram illustrating an atomic layer deposition apparatus according to an embodiment of the disclosure.

FIG. 18 illustrates a cross-section that corresponds to the cross section of FIG. 5. The following description will focus on components depicted in FIG. 18 different from those depicted in FIG. 5.

Referring to FIG. 18, an atomic layer deposition apparatus ADD-1 may include the first, second, and third valves VAL1, VAL2, and VAL3 that correspondingly connected to the first, second, and third pipes PIP1, PIP2, and PIP3. The first, second, and third pipes PIP1, PIP2, and PIP3 may be connected to a common pipe SPIP.

The common pipe SPIP may be connected to multiple distribution pipes DPIP. The distribution pipes DPIP may be connected to the first, second, and third source gas nozzles SNZ1, SNZ2, and SNZ3.

The first valve VAL1 may be connected to the first, second, and third source gas nozzles SNZ1, SNZ2, and SNZ3 through the first pipe PIP1, the common pipe SPIP, and the distribution pipes DPIP. The first source gas supply part SGP1 may be connected through the first valve VAL1 to the first, second, and third source gas nozzles SNZ1, SNZ2, and SNZ3.

The second valve VAL2 may be connected to the first, second, and third source gas nozzles SNZ1, SNZ2, and SNZ3 through the second pipe PIP2, the common pipe SPIP, and the distribution pipes DPIP. The second source gas supply part SGP2 may be connected through the second valve VAL2 to the first, second, and third source gas nozzles SNZ1, SNZ2, and SNZ3.

The third valve VAL3 may be connected to the first, second, and third source gas nozzles SNZ1, SNZ2, and SNZ3 through the third pipe PIP3, the common pipe SPIP, and the distribution pipes DPIP. The third source gas supply part SGP3 may be connected through the third valve VAL3 to the first, second, and third source gas nozzles SNZ1, SNZ2, and SNZ3.

Similar to the operation depicted in FIGS. 8A, 11a, and 14A, the first valve VAL1, the second valve VAL2, and the third valve VAL3 may be sequentially opened. The first source gas SG1 may be provided on the substrate SUB through the opened first valve VAL1, the first pipe PIP1, the common pipe SPIP, the distribution pipes DPIP, and the first, second, and third source gas nozzles SNZ1, SNZ2, and SNZ3.

The second source gas SG2 may be provided on the substrate SUB through the opened second valve VAL2, the second pipe PIP2, the common pipe SPIP, the distribution pipes DPIP, and the first, second, and third source gas nozzles SNZ1, SNZ2, and SNZ3.

The third source gas SG3 may be provided on the substrate SUB through the opened third valve VAL3, the third pipe PIP3, the common pipe SPIP, the distribution pipes DPIP, and the first, second, and third source gas nozzles SNZ1, SNZ2, and SNZ3.

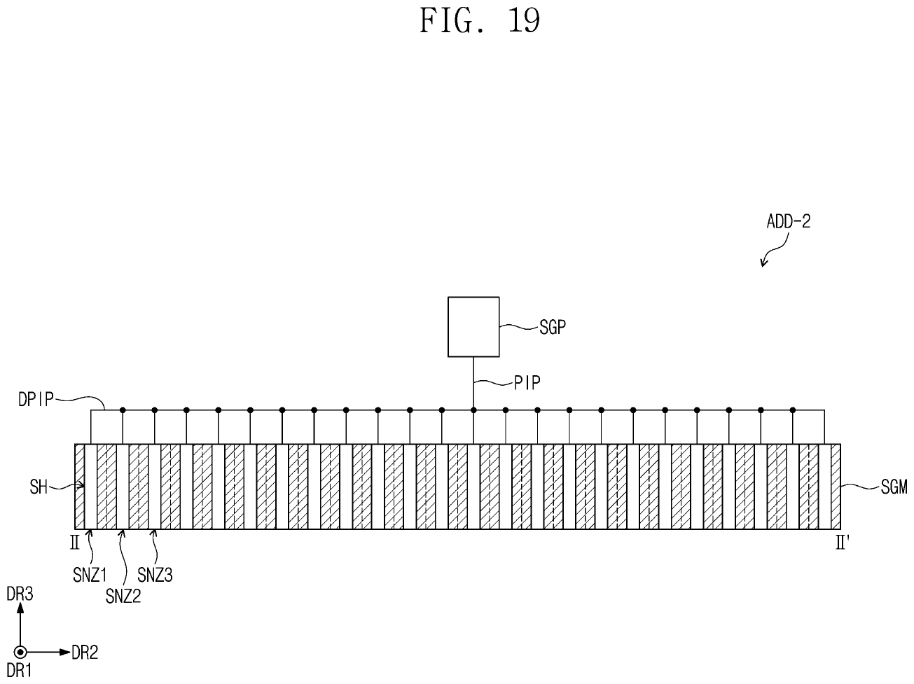

FIG. 19 is a schematic diagram illustrating an atomic layer deposition apparatus according to an embodiment of the disclosure.

FIG. 19 illustrates a cross-section that corresponds to the cross section of FIG. 5. The following description will focus on components depicted in FIG. 19 different from those depicted in FIG. 5.

Referring to FIG. 19, an atomic layer deposition apparatus ADD-2 may include the source gas supply part SGP, and the source gas supply part SGP may mix first, second, and third source gases and supply the mixed first, second, and third source gases to the source gas supply module SGM. For example, first, second, and third source gases in liquid states may be mixed in the source gas supply part SGP, and the mixed first, second, and third sources may be vaporized and supplied to the source gas supply module SGM.

The first, second, and third source gases may be mixed at different ratios. For example, in case that the thin layer to be deposited on the substrate SUB includes indium gallium zinc oxide (IGZO) is formed on the substrate SUB, indium (In), gallium (Ga), and zinc (Zn) may be mixed at a ratio of about 6:3:1 in the source gas supply part SGP.

In case that the first, second, and third source gases have no reaction between the first, second, and third source gases, the first, second, and third source gases may be mixed and supplied to the deposition module DM. For example, trimethyl indium (In), trimethyl ethyl gallium (Ga), and diethyl zinc (Zn) may have no reaction between the trimethyl indium (In), the trimethyl ethyl gallium (Ga), and the diethyl zinc (Zn), and may be used as the first, second, and third source gases and mixed with each other.

The source gas supply part SGP may supply the mixed first, second, and third source gases to the first, second, and third source gas nozzles SNZ1, SNZ2, and SNZ3 through a pipe PIP. The mixed first, second, and third source gases may be supplied through the first, second, and third source gas nozzles SNZ1, SNZ2, and SNZ3 onto the substrate SUB.

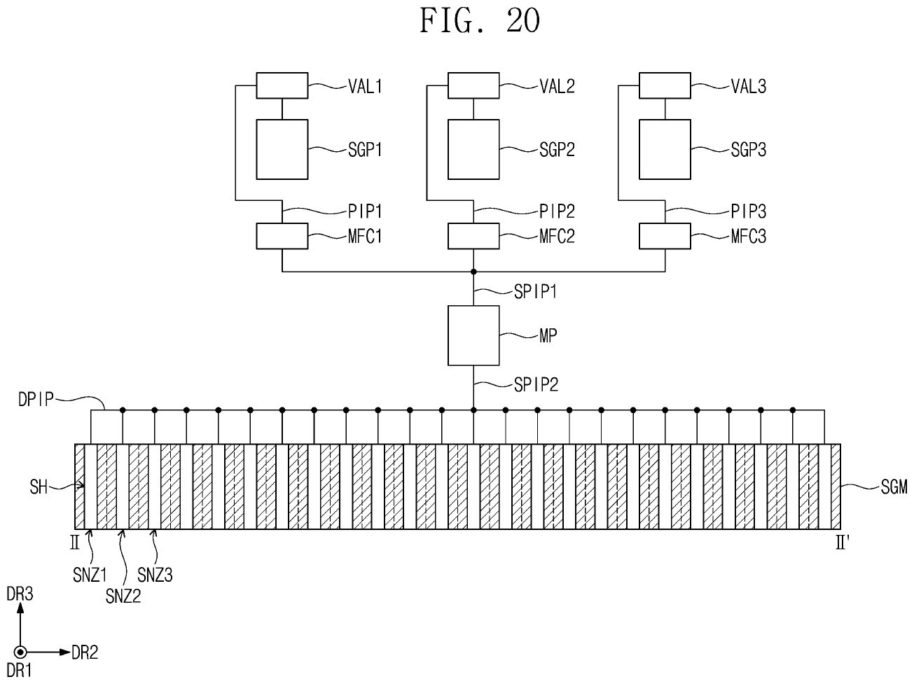

FIG. 20 is a schematic diagram illustrating an atomic layer deposition apparatus according to an embodiment of the disclosure.

FIG. 20 illustrates a cross-section that corresponds to the cross section of FIG. 5. The following description will focus on components depicted in FIG. 20 different from those depicted in FIG. 5.

Referring to FIG. 20, an atomic layer deposition apparatus ADD-3 may further include a first flow controller MFC1, a second flow controller MFC2, a third flow controller MFC3, and a mixture part MP.

The first flow controller MFC1 may be connected through the first pipe PIP1 to the first valve VAL1. The second flow controller MFC2 may be connected through the second pipe PIP2 to the second valve VAL2. The third flow controller MFC3 may be connected through the third pipe PIP3 to the third valve VAL3. The first, second, and third flow controllers MFC1, MFC2, and MFC3 may be connected in common to the mixture part MP to a first common pipe SPIP1.

The mixture part MP may be connected to a second common pipe SPIP2, the second common pipe SPIP2 may be connected to the distribution pipes DPIP, and the distribution pipes DPIP may be correspondingly connected to the first, second, and third source gas nozzles SNZ1, SNZ2, and SNZ3. For example, the mixture part MP may be connected to the first, second, and third flow controllers MFC1, MFC2, and MFC3 and to the first, second, and third source gas nozzles SNZ1, SNZ2, and SNZ3.

The first flow controller MFC1 may control a flow rate of a first source gas and provide the first source gas to the mixture part MP. The second flow controller MFC2 may control a flow rate of a second source gas and provide the second source gas to the mixture part MP. The third flow controller MFC3 may control a flow rate of a third source gas and provide the third source gas to the mixture part MP. Each of the first, second, and third flow controllers MFC1, MFC2, and MFC3 may include a mass flow controller.

The first, second, and third flow controllers MFC1, MFC2, and MFC3 may control the first, second, and third source gases to have different flow rates to supply the first, second, and third source gases to the mixture part MP with different ratios. For example, in case that the first, second, and third source gases include indium (In), gallium (Ga), and zinc (Zn), respectively, the first, second, and third flow controllers MFC1, MFC2, and MFC3 may control flow rates of the first, second, and third source gases, respectively, to supply the first, second, and third source gases to the mixture part MP with a ratio of about 6:3:1.

The first, second, and third source gases may be mixed in the mixture part MP, and may be provided through the distribution pipes DPIP to the first, second, and third source gas nozzles SNZ1, SNZ2, and SNZ3. The first, second, and third source gases mixed at different ratios may be supplied through the first, second, and third source gas nozzles SNZ1, SNZ2, and SNZ3 onto the substrate SUB.

According to an embodiment of the disclosure, with a single source gas supply module, multiple source gases may be provided through nozzles onto a substrate and multiple thin layers may be formed on the substrate. Therefore, as multiple source gas supply modules are not used, an atomic layer deposition apparatus may become small in size and a process may become simplified.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An atomic layer deposition apparatus, comprising:
a source gas supply part that supplies a plurality of source gases;
a source gas supply module connected to the source gas supply part;
a reaction gas supply part that supplies a reaction gas;
a reaction gas supply module connected to the reaction gas supply part and spaced apart from the source gas supply module in a first direction; and
a first purge gas supply module disposed between the source gas supply module and the reaction gas supply module.

2. The atomic layer deposition apparatus of claim 1, wherein the source gas supply part includes:
a first source gas supply part that supplies a first source gas;
a second source gas supply part that supplies a second source gas; and
a third source gas supply part that supplies a third source gas.

3. The atomic layer deposition apparatus of claim 2, wherein the source gas supply module includes:
a plurality of first source gas nozzles connected to the first source gas supply part;
a plurality of second source gas nozzles connected to the second source gas supply part; and
a plurality of third source gas nozzles connected to the third source gas supply part.

4. The atomic layer deposition apparatus of claim 3, wherein one of the plurality of first source gas nozzles, one of the plurality of second source gas nozzles, and one of the plurality of third source gas nozzles are repeatedly arranged in sequence.

5. The atomic layer deposition apparatus of claim 3, further comprising:
a first valve that connects the first source gas supply part to the plurality of first source gas nozzles and controls a supply of the first source gas;
a second valve that connects the second source gas supply part to the plurality of second source gas nozzles and controls a supply of the second source gas; and
a third valve that connects the third source gas supply part to the plurality of third source gas nozzles and controls a supply of the third source gas,
wherein the first, second, and third valves are sequentially opened.

6. The atomic layer deposition apparatus of claim 5, wherein
each of the first, second, and third valves includes a first valve part, a second valve part, a third valve part, and a fourth valve part,
an end of the first valve part and an end of the second valve part are connected to a corresponding one of the first, second, and third source gas supply parts,
another end of the second valve part is connected to an end of the third valve part,
another end of the first valve part is connected to another end of the third valve part,
the fourth valve part is supplied with a carrier gas and is connected to the end of the third valve part, and
the another end of the third valve part is connected to a corresponding one of the plurality of first source gas nozzles, the plurality of second source gas nozzles, and the plurality of third source gas nozzles.

7. The atomic layer deposition apparatus of claim 6, wherein
the source gas supply module receives and supplies the first, second, and third source gases to a substrate,
the reaction gas supply module receives and supplies the reaction gas to the substrate,
the first purge gas supply module supplies a purge gas to the substrate,
in case that the first, second, and third source gases are supplied, the first, second, and fourth valve parts are opened and the third valve part is closed, and
in case that supplies of the first, second, and third source gases are interrupted, the first and second valve parts are closed and the third and fourth valve parts are opened.

8. The atomic layer deposition apparatus of claim 6, further comprising:
a carrier gas supply part that supplies the carrier gas.

9. The atomic layer deposition apparatus of claim 1, further comprising:
a second purge gas supply module and a third purge gas supply module, wherein
the source gas supply module is disposed between the first purge gas supply module and the second purge gas supply module, and
the reaction gas supply module is disposed between the first purge gas supply module and the third purge gas supply module.

10. The atomic layer deposition apparatus of claim 1, wherein exhaust holes are defined between the source gas supply module and the first purge gas supply module and between the reaction gas supply module and the first purge gas supply module.

11. The atomic layer deposition apparatus of claim 10, further comprising:
a pumping module connected to the exhaust holes and providing an exhaust pressure to the exhaust holes.

12. The atomic layer deposition apparatus of claim 3, further comprising:
a first valve that connects the first source gas supply part to the plurality of first source gas nozzles, the plurality of second source gas nozzles, and the plurality of third source gas nozzles and controls a supply of the first source gas;
a second valve that connects the second source gas supply part to the plurality of first source gas nozzles, the plurality of second source gas nozzles, and the plurality of third source gas nozzles and controls a supply of the second source gas; and
a third valve that connects the third source gas supply part to the plurality of first source gas nozzles, the plurality of second source gas nozzles, and the plurality of third source gas nozzles and controls a supply of the third source gas,
wherein the first, second, and third valves are sequentially opened.

13. The atomic layer deposition apparatus of claim 12, further comprising:
a first flow controller connected to the first valve and controlling a flow rate of the first source gas;
a second flow controller connected to the second valve and controlling a flow rate of the second source gas;
a third flow controller connected to the third valve and controlling a flow rate of the third source gas; and
a mixture part connected to the first, second, and third flow controllers and to the plurality of first source gas nozzles, the plurality of second source gas nozzles, and the plurality of third source gas nozzles, mixing the first, second, and third source gases that are provided from the first, second, and third flow controllers, and supplying the mixed first, second, and third source gases to the plurality of first source gas nozzles, the plurality of second source gas nozzles, and the plurality of third source gas nozzles.

14. The atomic layer deposition apparatus of claim 13, wherein the flow rates of the first, second, and third source gases are independently controlled by the first, second, and third flow controllers.

15. The atomic layer deposition apparatus of claim 1, wherein
the source gas supply module includes a plurality of first source gas nozzles, a plurality of second source gas nozzles, and a plurality of third source gas nozzle, which supply different ones of the plurality of source gases,
each of the plurality of first source gas nozzles includes a first source hole,
each of the plurality of second source gas nozzles includes a second source hole,
each of the plurality of third source gas nozzles includes a third source hole,
the first source hole, the second source hole, and the third source hole of neighboring ones of the plurality of first source gas nozzles, the plurality of second source gas nozzles, and the plurality of third source gas nozzles are arranged in a diagonal direction,
the diagonal direction is a direction that intersects the first direction and a second direction intersecting the first direction, and
the source gas supply module extends in the second direction.

16. The atomic layer deposition apparatus of claim 1, wherein the plurality of source gases are mixed in the source gas supply part and are supplied to the source gas supply module.

17. The atomic layer deposition apparatus of claim 16, wherein the plurality of source gases are mixed at different ratios.

18. An atomic layer deposition apparatus, comprising:
a first source gas supply part that supplies a first source gas;
a second source gas supply part that supplies a second source gas;
a third source gas supply part that supplies a third source gas;
a source gas supply module connected to the first, second, and third source gas supply parts;
a first valve that connects the first source gas supply part to the source gas supply module and controls a supply of the first source gas;
a second valve that connects the second source gas supply part to the source gas supply module and controls a supply of the second source gas;
a third valve that connects the third source gas supply part to the source gas supply module and controls a supply of the third source gas;
a reaction gas supply part that supplies a reaction gas;
a reaction gas supply module connected to the reaction gas supply part and spaced apart from the source gas supply module in a first direction; and
a first purge gas supply module disposed between the source gas supply module and the reaction gas supply module.

19. The atomic layer deposition apparatus of claim 18, wherein the first, second, and third valves are sequentially opened.

20. The atomic layer deposition apparatus of claim 18, wherein the source gas supply module includes:
a plurality of first source gas nozzles connected through the first valve to the first source gas supply part;
a plurality of second source gas nozzles connected through the second valve to the second source gas supply part; and
a plurality of third source gas nozzles connected through the third valve to the third source gas supply part.
